(19) United States
(12) Patent Application Publication
(10) Pub. No.: US 2026/0297299 A1
(43) Pub. Date: Oct. 1, 2026

(54) STAGED INJECTOR TO ENHANCE STRUCTURE OF RECLAIMED CARBON BLENDS

(71) Applicant: Cabot Corporation, Boston, MA (US)

(72) Inventors: Theis F. Clarke, Houston, TX (US); Thomas E. McElwain, Pampa, TX (US); Patricia A. Hubbard, Weston, MA (US); Michael Zhang, Westford, MA (US)

(21) Appl. No.: 19/631,002

(22) Filed: Mar. 27, 2026

Related U.S. Application Data
(60) Provisional application No. 63/781,919, filed on Apr. 1, 2025.
(60) Provisional application No. 63/785,329, filed on Apr. 8, 2025.
(60) Provisional application No. 63/859,441, filed on Aug. 7, 2025.
(60) Provisional application No. 63/903,922, filed on Oct. 23, 2025.

(51) Int. Cl. C08K 9/02; B60C 1/00; C09C 1/50; C09C 1/56

(52) U.S. Cl. CPC C08K 9/02; C09C 1/50; C09C 1/56; B60C 1/0008; B60C 1/0016; B60C 1/0025; C01P 2002/85; C01P 2004/84; C01P 2006/19

(57) ABSTRACT

A method of making a particulate carbon product includes: introducing to a reactor a first carbon black forming feedstock and combining the first carbon black-forming feedstock with a stream of hot gases to form a precursor comprising a reaction stream and a particulate comprising at least 98% carbon black; introducing reclaimed carbon particles to the precursor to form a blended stream of the carbon black and the reclaimed carbon particles in the reaction stream; introducing a second feedstock to the blended stream wherein at least a portion of the particulate in the blended stream becomes carbon-coated particles, thereby forming a particulate carbon product comprising the carbon-coated particles; and recovering the particulate carbon product.

### BACKGROUND

### 1. Field

The embodiments and implementations presented herein relate to methods to increase the structure of reclaimed carbon particulates.

### 2. Description of the Related Art

There is more and more demand and effort in the recycling of materials to avoid the materials being disposed of in waste fills and to avoid further depletion of natural resources.

End-of-life vehicle tires are frequently processed and reused in a wide range of end-use applications from playground equipment to concrete. However, it is desirable to recycle components of tires to obtain materials that can be combined with first-use materials to reduce the amount of new material required to produce new products.

There is a growing need for more sustainable materials and reduced carbon footprint in various industries. Thus, the use of reclaimed carbon (rC) from used tires (or other sources) as a substitute for carbon black (CB) in rubber reinforcement applications may be a promising strategy. Tires and other rubbers contain a variety of carbon blacks and other fillers having a variety of morphologies, along with ceramic additives such as zinc oxide. Consequently, the resulting rC has a different composition and microstructure than virgin carbon black. Reclaimed carbon suffers from low rubber reinforcement, such as low tensile modulus, low tear strength, and/or low fatigue life, compared with CB with the same or about the same surface area and structure as measured by COAN. Accordingly, there is a need in the industry to develop processes that can take rC and other similar particles that are not suitable as-is for use as filler in rubber reinforcement applications and other applications so as to make them a suitable replacement or suitable partial replacement for virgin carbon black.

### SUMMARY

In an embodiment, a method of making a particulate carbon product comprises introducing to a reactor a first carbon black forming feedstock and combining the first carbon black-forming feedstock with a stream of hot gases to form a precursor comprising a reaction stream and a particulate comprising at least 98% carbon black; introducing reclaimed carbon particles to the precursor to form a blended stream of the carbon black and the reclaimed carbon particles in the reaction stream; introducing a second feedstock to the blended stream wherein at least a portion of the particulate in the blended stream becomes carbon-coated particles, thereby forming a particulate carbon product comprising the carbon-coated particles; and recovering the particulate carbon product.

The carbon-coated particles may be at least 10% coated with carbon resulting from pyrolysis of the second feedstock, for example, at least 15%, at least 20%, at least 25%, at least 30%, at least 35%, at least 40%, at least 45%, at least 50%, at least 55%, at least 60%, at least 65%, at least 70%, at least 75%, at least 80%, at least 85%, at least 90%, at least 95%, or at least 99%.

Alternatively or in addition, the first carbon black feedstock may be a liquid at room temperature and pressure, and may have the following properties:
a Bureau of Mines Correlation Index (BMCI)≥100,
an atomic H:C ratio of ≤1.23, and
a specific gravity>1.02, and
   wherein the second feedstock may have at least one of the following properties:
a Bureau of Mines Correlation Index (BMCI)<100, or
an atomic H:C ratio of >1.23, or
a specific gravity of ≤1.02, or
is a gas at room temperature and pressure.

Alternatively or in addition, first feedstock and the second feedstock may both be liquid at room temperature and pressure. The first feedstock may be 30%-70% by mass of the total carbon black yielding feedstock introduced to the reactor. The second feedstock may be 30%-70% by mass of the total carbon black yielding feedstock introduced to the reactor.

Alternatively or in addition, the method may further comprise forming the stream of hot gases in a combustion zone having a diameter, and introducing the first carbon black-forming feedstock in a throat having a diameter Dt smaller than the diameter of the combustion zone, wherein a jet time from a first plane in which the first feedstock is introduced to the reactor and a second plane in which the second feedstock is from 27 ms to 100 ms, wherein the jet time is (distance from the first plane to the second plane)/((volumetric flow of combustion air under normal conditions)/(area of throat)). As used herein, normal conditions indicates 20 deg C. and 1 atmosphere of pressure.

Alternatively or in addition, introduction of the second feedstock may further result in production of carbon black. At least a portion of the carbon black in the blended stream may become carbon-coated particles as a result of introducing the second feedstock. At least a portion of the reclaimed carbon particles in the blended stream may become carbon-coated particles as a result of introducing the second feedstock. A jet time from a first plane in which the first feedstock is introduced to the reactor to a third plane where the reclaimed carbon is introduced to the reactor is from 7 ms to 21 ms, wherein the jet time is defined as (distance from the first plane to the third plane)/((volumetric flow of combustion air under normal conditions)/(cross-sectional area of first plane)).

In any of these embodiments, a feed rate of the reclaimed carbon into the reactor may from 0.1 kg/hr to 1800 kg/hr or higher, for example, from 1 kg/hr to 100 kg/hr, from 100 kg/hr to 200 kg/hr, from 150 kg/hr to 300 kg/hr, from 250 kg/hr to 450 kg/hr, from 300 kg/hr to 500 kg/hr, from 500 kg/hr to 1000 kg/hr, from 700 kg/h to 1200 kg/hr, from 1000 kg/hr to 1500 kg/hr, or from 1500 kg/hr to 1800 kg/hr. In some embodiments, the feed rate of reclaimed carbon may be as high as 10,000 kg/hr, for example, from 1800 kg/hr to 3000 kg/hr, from 3000 kg/hr to 5000 kg/hr, from 5000 kg/hr to 7000 kg/hr, or from 7000 kg/hr to 10,000 kg/hr. The reclaimed carbon may be injected into the reactor via ports distributed about a circumference of a cross-sectional of the reactor. The reclaimed carbon may be injected into the reactor via a lance projecting into the interior of the reactor. The reclaimed carbon may be injected into the reactor in a blend with air or with an inert gas.

In any of these embodiments, the second feedstock may be injected via a lance projecting into the interior of the reactor. The second feedstock may be injected into the reactor via one or more radial lances or injectors arranged on the circumference of the reactor. A feed rate of the second feedstock may be 180 to 5000 kg/hr, for example, 190 kg/hr to 350 kg/hr, 350 kg/hr to 700 kg/hr, 700 kg/hr to 1000 kg/hr, 1000 kg/hr to 1500 kg/hr, 1500 kg/hr to 2000 kg/hr, 2000 kg/hr to 2500 kg/hr, 2500 kg/hr to 3000 kg/hr, 3000 kg/hr to 3500 kg/hr, 3500 kg/hr to 4000 kg/hr, 4000 kg/hr to 4500 kg/hr, or 4500 kg/hr to 5000 kg/hr.

Alternatively or in addition, first feedstock, the second feedstock, or both may be preheated prior to injection into the reactor. The final particulate carbon product may comprise at least 15% (by mass) material that originated as reclaimed carbon, for example, from 20% to 70%, from 25% to 40%, from 15% to 35%, from 30% to 50%, from 40% to 60%, or from 50% to 70%. The particulate carbon product may have a COAN according to ASTM D3493 of 85 to 145 mL/100 g, for example, from 95 to 140 mL/100 g, from 100 to 135 mL/100 g, from 105 to 130 mL/100 g, from 110 to 125 mL/100 g, or from 110 to 120 mL/100 g.

In any of these embodiments, a particulate carbon product comprising carbon-coated reclaimed carbon may have a ratio Si/C as measured by energy dispersive x-ray spectroscopy (EDS) (Si/C (EDS)) and a ratio Si/C as measured by x-ray photoelectron spectroscopy (XPS) (Si/C (XPS)) satisfying Si/C (XPS)÷Si/C (EDS) of at most 1, at most 0.9, at most 0.8, at most 0.7, at most 0.6, at most 0.5, or from 0.1 to 1, from 0.2 to 0.9, or from 0.3 to 0.8, and a tensile stress at 300% strain of an elastomer composite comprising 40-60 phr of the particulate carbon product may be at least 95% as great, for example, from 97% to 140% as great, from 99% to 130% as great, from 101% to 120% as great, or from 103% to 115% as great, as the tensile stress at 300% strain of an elastomer composite prepared in the same manner and with the same formulation but with N330 carbon black substituted for the particulate carbon product.

In any of these embodiments, a particulate carbon product comprising carbon-coated reclaimed carbon may have a ratio Si/C as measured by energy dispersive x-ray spectroscopy (EDS) (Si/C (EDS)) and a ratio Si/C as measured by x-ray photoelectron spectroscopy (XPS) (Si/C (XPS)) satisfying Si/C (XPS)÷Si/C (EDS) from 0.1 to 1, for example, from 0.2 to 0.9 or from 0.3 to 0.8. A vulcanized elastomer composite may comprise the particulate carbon product having any of these characteristics.

In any of these embodiments, a particulate carbon product comprising carbon-coated reclaimed carbon may have a ratio Si/C as measured by x-ray photoelectron spectroscopy (XPS) (Si/C (XPS)) of at most 1%, for example, from 0.2% to 0.5% or from 0.2% to 0.35% and a tensile stress at 300% strain of an elastomer composite comprising 40-60 phr of the particulate carbon product may be at least 95% as great, for example, from 97% to 140% as great, from 99% to 130% as great, from 101% to 120% as great, or from 103% to 115% as great, as the tensile stress at 300% strain of an elastomer composite prepared in the same manner and with the same formulation but with ASTM N330 carbon black substituted for the particulate carbon product.

In any of these embodiments, a particulate carbon product comprising carbon-coated reclaimed carbon may have a ratio Si/C as measured by x-ray photoelectron spectroscopy (XPS) (Si/C (XPS)) of 0.2-1%, for example, from 0.2% to 0.5% or from 0.2% to 0.35% A vulcanized elastomer composite may comprise the particulate carbon having some or all of these characteristics.

In any of these embodiments, a particulate carbon product comprises carbon-coated reclaimed carbon, and in comparison to a vulcanizate containing an equivalent amount of ASTM N330 type carbon black and that is compounded and vulcanized in the same manner, a vulcanizate containing 40-60 phr of the particulate carbon product may have a log (base 10) resistivity from 105 to 125% as great, for example, from 107 to 123% as great, or from 110% to 120% as great and a tensile stress at 300% strain at least 95% as great, for example, from 97% to 140% as great, from 99% to 130% as great, from 101% to 120% as great, or from 103% to 115% as great.

In any of these embodiments, a particulate carbon product comprises carbon-coated reclaimed carbon, and in comparison to a vulcanizate containing an equivalent amount of reclaimed carbon that is compounded and vulcanized in the same manner, a vulcanizate containing 40-60 phr of the particulate carbon product may have a log (base 10) resistivity from 55% to 85% as great, for example, from 55% to 75% as great, and a tensile stress at 300% strain that is at least 35% greater, for example, from 35% to 70% greater, from 40% to 65% greater, or from 45% to 65% greater than the tensile stress at 300% strain of an elastomer composite prepared in the same manner but with the uncoated reclaimed carbon substituted for the particulate carbon product.

In any of these embodiments, a particulate carbon product comprises carbon-coated reclaimed carbon, and a vulcanizate containing 40-60 phr of the particulate carbon product has a log (base 10) resistivity from 55% to 85% as great, for example, from 55% to 75% as great, and a tensile stress at 300% strain that is at least 35% greater, for example, from 35% to 70% greater, from 40% to 65% greater, or from 45% to 65% greater than the tensile stress at 300% strain of a vulcanizate prepared in the same manner and with the same formulation but with a reclaimed carbon, for example, a reclaimed carbon having 10-25 wt % ash, that has not been carbon-coated substituted for the particulate carbon product.

In any of these embodiments, the particulate carbon product may comprise at least 15% (by mass) reclaimed carbon, for example, from 20% to 70%, from 25% to 40%, from 15% to 35%, from 30% to 50%, from 40% to 60%, or from 50% to 70%. Alternatively or in addition, the particulate carbon product may have a COAN according to ASTM D3493 of 85 to 145 mL/100 g, for example, from 95 to 140 mL/100 g, from 100 to 135 mL/100 g, from 105 to 130 mL/100 g, from 110 to 125 mL/100 g, or from 110 to 120 mL/100 g.

In any of these embodiments, a vulcanized elastomer composite comprising at least one elastomer and 40-60 phr of a particulate carbon product comprising carbon-coated reclaimed carbon may have a ratio Si/C of the particulate carbon product as measured by energy dispersive x-ray spectroscopy (EDS) (Si/C (EDS)) and a ratio Si/C as measured by x-ray photoelectron spectroscopy (XPS) (Si/C (XPS)) satisfy Si/C (XPS)÷Si/C (EDS) of at most 1, for example, at most 0.9, at most 0.8, at most 0.7, at most 0.6, at most 0.5, or from 0.1 to 1, from 0.2 to 0.9, or from 0.3 to 0.8, and a tensile stress at 300% strain of the elastomer composite may be at least 95% as great, for example, from 97% to 140% as great, from 99% to 130% as great, from 101% to 120% as great, or from 103% to 115% as great, as the tensile stress at 300% strain of an elastomer composite prepared in the same manner and with the same formulation but with N330 carbon black substituted for the particulate carbon product.

In any of these embodiments, a vulcanized elastomer composite comprising at least one elastomer and 40-60 phr of a particulate carbon product comprising carbon-coated reclaimed carbon may have a ratio Si/C of the particulate carbon product as measured by x-ray photoelectron spectroscopy (XPS) (Si/C (XPS)) of at most 1%, for example, from 0.2% to 0.5% or from 0.2% to 0.35%, and a tensile stress at 300% strain of the elastomer composite may be at least 95% as great, for example, from 97% to 140% as great, from 99% to 130% as great, from 101% to 120% as great, or from 103% to 115% as great, as the tensile stress at 300% strain of an elastomer composite prepared in the same manner and with the same formulation but with ASTM N330 carbon black substituted for the particulate carbon product.

In any of these embodiments, a vulcanized elastomer composite comprising at least one elastomer and 40-60 phr of a particulate carbon product comprising carbon-coated reclaimed carbon may have, in comparison to a vulcanizate containing an equivalent amount of ASTM N330 type carbon black and that is compounded and vulcanized in the same manner, a log (base 10) resistivity from 105 to 125% as great, for example, from 107 to 123% as great, or from 110% to 120% as great and a tensile stress at 300% strain at least 95% as great, for example, from 97% to 140% as great, from 99% to 130% as great, from 101% to 120% as great, or from 103% to 115% as great.

In any of these embodiments, a vulcanized elastomer composite comprising at least one elastomer and 40-60 phr of a particulate carbon product comprising carbon-coated reclaimed carbon may have a log (base 10) resistivity from 55% to 85% as great, for example, from 55% to 75% as great, and a tensile stress at 300% strain that is at least 35% greater, for example, from 35% to 70% greater, from 40% to 65% greater, or from 45% to 65% greater than the tensile stress at 300% strain of a vulcanized elastomer composite prepared in the same manner and with the same formulation but with the uncoated reclaimed carbon substituted for the particulate carbon product.

In any of these embodiments, a vulcanized elastomer composite comprising at least one elastomer and 40-60 phr of a particulate carbon product comprising carbon-coated reclaimed carbon may have a log (base 10) resistivity from 55% to 85% as great, for example, from 55% to 75% as great, and a tensile stress at 300% strain that is at least 35% greater, for example, from 35% to 70% greater, from 40% to 65% greater, or from 45% to 65% greater than the tensile stress at 300% strain of an elastomer composite prepared in the same manner and with the same formulation but with an uncoated reclaimed carbon, for example an uncoated reclaimed carbon having 10-25 wt % ash, substituted for the particulate carbon product.

In any of these embodiments, the elastomer may be selected from natural rubbers, functionalized natural rubbers, styrene-butadiene rubbers, functionalized styrene-butadiene rubbers, polybutadiene rubbers, functionalized polybutadiene rubbers, polyisoprene rubbers, ethylene-propylene copolymers, isobutylene-based rubbers, polychloroprene rubbers, nitrile rubbers, hydrogenated nitrile rubbers, polysulfide rubbers, polyacrylate elastomers, fluoroelastomers, perfluoroelastomers, co-polymers of any of the above, blends of any of the above, and oil-extended derivatives of any of the above.

In any of these embodiments, the particulate carbon product may comprise at least 15% (by mass) reclaimed carbon, for example, from 20% to 70%, from 25% to 40%, from 15% to 35%, from 30% to 50%, from 40% to 60%, or from 50% to 70%. Alternatively or in addition, the particulate carbon product may have a COAN according to ASTM D3493 of 85 to 145 mL/100 g, for example, from 95 to 140 mL/100 g, from 100 to 135 mL/100 g, from 105 to 130 mL/100 g, from 110 to 125 mL/100 g, or from 110 to 120 mL/100 g.

In any of these embodiments, an article comprising the vulcanized elastomer composite may be selected from tire treads, undertread, innerliners, sidewalls, sidewall inserts, wire-skim, and cushion gum for retread tires.

In any of these embodiments, an article comprising the vulcanized elastomer composite may be selected from hoses, linings, liners, seals, gaskets, anti-vibration articles, tracks, track pads for track-propelled vehicle equipment, engine mounts, earthquake stabilizers, mining equipment screens, mining equipment linings, conveyor belts, chute liners, slurry pump liners, mud pump impellers, valve seats, valve bodies, piston hubs, piston rods, plungers, impellers for mixing slurries and slurry pump impellers, grinding mill liners, cyclones and hydrocyclones, expansion joints, linings for dredge pumps and outboard motor pumps for marine equipment, shaft seals for marine, oil, aerospace, and other applications, propeller shafts, pipe linings, engine mounts, bushings, weather stripping, windshield wipers, automotive components, seals, gaskets, housings, wheel elements, and track elements.

As used herein, “char” means solid material resulting from pyrolysis of rubber goods.

As used herein, “milled reclaimed carbon” or “milled rC” is pyrolysis carbon that is substantially free of macroscopic contaminants and that has been milled and optionally pelletized.

As used herein, “carbon black” means elemental carbon-containing particles of carbon obtained by partial combustion or thermal decomposition of hydrocarbons. These carbon-containing particles may be coalesced into aggregates and agglomerates or coated onto a substrate such as reclaimed carbon.

As used herein, “raw reclaimed carbon” is solid material resulting from pyrolysis of rubber goods that contain at least two different types of carbonaceous particulate fillers, including but not limited to carbon black (e.g., at least two different types of carbon black), in any amount.

As used herein, “processed reclaimed carbon” means raw reclaimed carbon that has been processed to remove at least one macroscopic contaminant such as fabric or wire.

As used herein, “pyrolysis carbon” includes char, raw reclaimed carbon, processed reclaimed carbon, and dry milled reclaimed carbon.

As used herein, “reclaimed carbon” or “rC” is raw reclaimed carbon that has been processed to remove macroscopic contaminants and that has optionally been further milled.

Thus, processed reclaimed carbon and milled reclaimed carbon both fall under the definition of reclaimed carbon.

It is to be understood that both the foregoing general description and the following detailed description are exemplary and explanatory only and are intended to provide further explanation related to the present claims.

### BRIEF DESCRIPTION OF THE DRAWING

Various embodiments are described with reference to the several figures of the drawing, in which,

FIGS. 1 and 2 are schematic diagrams of apparatus for implementing exemplary embodiments of the methods provided herein.

### DETAILED DESCRIPTION

In one embodiment, a method of making a particulate carbon product includes introducing to a reactor a first carbon black forming feedstock and combining the first carbon black-forming feedstock with a stream of hot gases to form a precursor comprising a reaction stream and a particulate comprising at least 98% carbon black, introducing reclaimed carbon particles to the precursor to form a blended stream of the in-process carbon black and the reclaimed carbon particles in the reaction stream, introducing a second feedstock to the blended stream wherein at least a portion of the particulate in the blended stream become carbon-coated particles, thereby forming a particulate carbon product comprising the carbon-coated particles, and recovering the particulate carbon product.

The particulate carbon product is a blend of virgin carbon black and reclaimed carbon black. Introducing the second feedstock to the blended stream causes at least a portion of the first carbon black to become partially or completely coated with additional carbon black. Moreover, introducing the second feedstock to the blended stream causes at least a portion of the reclaimed carbon particles to become partially or completely coated with carbon black via a pyrolysis process, thereby increasing COAN of the coated reclaimed carbon particles.

It has been unexpectedly discovered that introducing reclaimed carbon into a stream of in-process carbon black and hot gases, followed by introducing additional carbon-forming feedstock, increases COAN of the processed material more than introducing reclaimed carbon into a stream of hot gases not containing carbon black, followed by injection of carbon black feedstock in one or more stages.

The starting reclaimed carbon or rC (to be subjected to milling), such as rC aggregates, are commercially available. Generally, the rC aggregates result from the pyrolysis of tires and/or other rubber materials that contained filler materials or reinforcement materials, such as carbon black. The rC is made primarily of carbon black that was used to reinforce rubber. The rC can contain components that can pyrolyze, such as the rubber components. The rC can be processed reclaimed carbon where the raw reclaimed carbon has been processed to remove or substantially remove at least one macroscopic contaminant such as fabric or wire. The reclaimed carbon is commercially available from such suppliers as Reoil Sp. z o.o., Philbro rCB, Scandinavian Enviro Systems AB, Pyrum Innovations AG, or Bolder Industries or CBp Cyprus Ltd.

The rC may be processed to remove macroscopic contaminants. For example, magnetic separation techniques known to those of skill in the art may be used to remove wires and other macroscopic metallic contaminants. Filters or screens may be used to remove fabric and other non-magnetic macroscopic contaminants. The rC may be processed to remove macroscopic contaminants.

Alternatively or in addition, the rC or pyrolysis carbon may be processed to remove ash, for example, by washing the pyrolysis carbon with acid or by using an ion exchanger. Exemplary methods are described in US20150307714, CN101357758, and WO2021/005124, the contents of all of which are incorporated herein by reference.

Alternatively or in addition, the rC may be milled. For example, the rC may be milled as described in WO2023/122582 or WO2025/006552, the entire contents of both of which are incorporated by reference.

In certain embodiments, the blended particulate carbon is produced using a carbon black furnace, process, and/or reactor. A variety of such are known in the art. Examples include but are not limited to those described U.S. Pat. Nos. RE28974, 5,877,238, 5,190,739, WO2014140228, U.S. Pat. Nos. 6,277,350, 7,097,922, 4,582,695, 6,099,818, 6,056,933, 6,391,274, 8,289,057, and US20070104636, the contents of all of which are incorporated herein by reference.

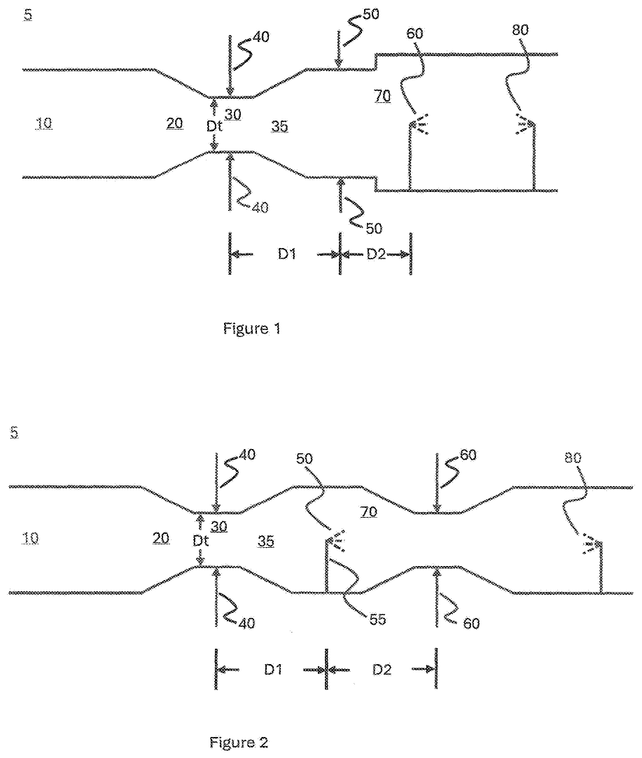

In the embodiment shown in FIG. 1, hot combustion gases are generated in combustion zone 10 of a reactor 5 by contacting a fuel stream with a gas stream containing an oxidant. The gas stream may be, for example, air, oxygen, or blends thereof. The fuel stream and the gas stream are generally introduced into combustion zone 10 either separately or as a mixture and ignited by any suitable method. The fuel can be any readily combustible gas, vapor, or liquid stream. Exemplary fuels include but are not limited to hydrocarbons such as methane, natural gas, and acetylene, hydrogen, alcohols, kerosene, and mixtures of any of these. Either or both of the fuel stream or the gas stream may be pre-heated prior to introduction into combustion zone 10.

The hot combustion gases flow from combustion zone 10 into narrowing zone 20 and throat 30 having diameter Dt, which may be from 2 inches (5.1 cm) to 19 inches (48.3 cm). A first carbon black forming feedstock 40 is injected into either narrowing zone 20 or throat 30, as shown in FIG. 1. Alternatively or in addition, the first feedstock may be introduced via a central pipe or lance located in combustion zone 10 or narrowing zone 20. Such a central pipe can be positioned approximately on the centerline of the reactor. The central pipe may have an injector head having one, two or more holes around the tip or a spray head. Alternatively or in addition, the first carbon black feedstock may be injected radially from the walls of narrowing zone 20 or throat 30 into the hot combustion gases. In this embodiment the first feedstock is introduced via one or more radial injectors or lances arranged on the circumference of the reactor in narrowing zone 20 or in throat 30, as shown in FIG. 1, in a plane perpendicular to the flow direction. The first feedstock may be heated as described in U.S. Pat. No. 9,574,087, the entire contents of which are incorporated herein by reference. The first carbon black forming feedstock 40 may be 30%-70% by mass of the total carbon black forming feedstock injected into reactor 5, for example, 40%-60% or 45%-55% of the total carbon black forming feedstock.

The first feedstock may be any carbon-bearing feedstock suitable for producing carbon black. Preferably, the first feedstock is a liquid at room temperature and pressure and has the following properties: a Bureau of Mines Correlation Index (BMCI)≥100, an atomic H:C ratio of ≤1.23, and a specific gravity>1.02. Examples of such feedstocks include but are not limited to decant oil, slurry oil, coker oil, coal tar derivatives, and heavy liquid residues from ethylene cracker processes.

The mixture of the first feedstock into the hot combustion gases results in formation of a precursor comprising a reaction stream and a particulate material primarily containing carbon black. At most 2 wt % of the particulate may include ash, sulfur, or other impurities resulting from impurities in the first feedstock. Carbon black is formed in the reactor by pyrolysis of the feedstock and polymerization of the pyrolyzed species to form carbon black precursors that condense into seed particles and onto existing seed particles, while the seed particles themselves coalesce into larger particles which aggregate and grow by deposition of additional carbon black precursors. The carbon black in the reaction stream prior to addition of the reclaimed carbon may include any of these intermediate materials, which may not have the same morphology as carbon black exiting reactor 5 after quench 80.

Reclaimed carbon 50 is injected into the reaction stream carrying the particulate material. The reclaimed carbon 50 may be processed reclaimed carbon or milled reclaimed carbon or a blend of these in any proportion. The reclaimed carbon may be injected into the reactor in any manner known to those of skill in the art. For example, the reclaimed carbon can be pumped into the reactor 5 using any suitable pump for particulates, for example, an air operated diaphragm or double diaphragm pump, a flap valve pump, a centrifugal pump, or a disc pump. In certain embodiments, no more carrier gas is required beyond that which passes through the pump with the reclaimed carbon. The carrier gas may be air or may be some other gas, for example, an inert gas. Any alternative means known to those of skill in the art for conveying the reclaimed carbon may also be employed. The carrier gas may be preheated by passing it through a heat exchanger or via other methods known to those of skill in the art. The feed rate of the reclaimed carbon into the reactor 5 may be from 0.1 kg/hr to 1800 kg/hr or higher, for example, from 1 kg/hr to 100 kg/hr, from 100 kg/hr to 200 kg/hr, from 150 kg/hr to 300 kg/hr, from 250 kg/hr to 450 kg/hr, from 300 kg/hr to 500 kg/hr, from 500 kg/hr to 1000 kg/hr, from 700 kg/h to 1200 kg/hr, from 1000 kg/hr to 1500 kg/hr, or from 1500 kg/hr to 1800 kg/hr. In some embodiments, the feed rate of reclaimed carbon may be as high as 10,000 kg/hr, for example, from 1800 kg/hr to 3000 kg/hr, from 3000 kg/hr to 5000 kg/hr, from 5000 kg/hr to 7000 kg/hr, or from 7000 kg/hr to 10,000 kg/hr. The limits on the feed rate of reclaimed carbon are dictated by the ability to produce the corresponding amount of carbon black in the reactor depending on the desired proportion of carbon black and reclaimed carbon in the final product.

The reclaimed carbon 50 may be injected via ports distributed about the circumference of the reactor 5, as shown in FIG. 1. Alternatively, reclaimed carbon 50 may be injected via one or more lances projecting into the interior of reactor 5. Such a lance (e.g., lance 55) may project all the way to the center axis of reactor 5, as shown in FIG. 2, meaning that the length of the lance is the same as the radius r of reactor 5. Alternatively, one or more lances may project in a fraction of radius r, for example, 0.1r-0.3r, 0.2r-0.4r, 0.3r-0.5r, 0.4r-0.6r, 0.5r-0.7r, 0.6r-0.8r, 0.7r-0.9r, or 0.8r-1r. A distance D1 from the plane where first feedstock 40 is injected to where the reclaimed carbon 50 is injected may correspond to a jet time of 7 ms to 21 ms, where jet time is defined as distance in reactor/((volumetric flow of combustion air under normal conditions)/(area of throat)), here D1/((volumetric flow of combustion air under normal conditions)/(area of throat)). Preferably, the radius r of reactor 5 in the plane where reclaimed carbon 50 is injected is greater than Dt, for example, from 1.3 to 8 times Dt. In some embodiments, reactor 5 has a widening section 35 between throat 30 and reaction zone 70, and reclaimed carbon 50 is introduced to the precursor downstream of widening section 35 in a region of reaction zone 70 having constant diameter. Reaction zone 70 may have a diameter from 1.3 Dt to 8 Dt, for example, 1.5 Dt to 3 Dt, 2.5 Dt to 4 Dt, 3.5 Dt to 5 Dt, 4.5 Dt to 6 Dt, 5.5 Dt to 7 Dt, or 6.5 Dt to 8 Dt.

The reclaimed carbon mixes with carbon black in the reaction stream to form a blended stream. A second feedstock 60 is then injected into the blended stream. The second feedstock 60 may be any carbon bearing feedstock suitable for producing carbon black, including any of the feedstocks described as appropriate for the first feedstock. The second feedstock 60 may be the same or different than the first feedstock. In certain embodiments, the second feedstock has at least one of the following properties: a Bureau of Mines Correlation Index (BMCI)<40, or an atomic H:C ratio of >1.23, or a specific gravity of ≤1.02, or is a gas at room temperature and pressure (collectively, “low-yielding feedstock properties”). The second feedstock may have the BMCI property. The second feedstock may have the atomic H:C property. The second feedstock may have the specific gravity property. Alternatively, the second feedstock may have the BMCI and the atomic H:C properties. Alternatively, the second feedstock may have BMCI property and the specific gravity properties. Alternatively, the second feedstock may have the atomic H:C and the specific gravity properties. Alternatively, the second feedstock may have the BMCI, atomic H:C, and specific gravity properties. Such feedstocks typically result in lower yields, lower surface areas, and/or lower structures in furnace black processes in comparison to traditional feedstocks such as decant oil. However, in certain embodiments, use of these “lower yielding” feedstocks, especially in liquid form, as the second feedstock 60 result in increased structure development, as measured by COAN, with respect to feedstocks not having at least one of the quantitative low yielding feedstock properties.

In certain embodiments, the second feedstock 60 is a low yielding feedstock that is a gas at room temperature and pressure, e.g., natural gas or ethylene. In preferred embodiments, the second feedstock is a liquid at room temperature and pressure (e.g., 25° C. at 1 atm). Examples of low-yielding liquid carbon black feedstocks can include, but are not limited to, the following: a tire pyrolysis oil, a plastic pyrolysis oil, a recycled oil, an algal oil, a plant-derived oil, an oil derived from pyrolysis of municipal solid waste, an oil derived from the pyrolysis or decay of biomass (e.g., animal or vegetable) or agricultural waste, an oil derived from the processing of pulp or paper production byproducts, and/or another oil sourced primarily from biomaterials or any combinations thereof. Exemplary low-yielding feedstocks include but are not limited to a vegetable or other plant-derived oil, a bio-sourced ethanol, a plant- or animal-produced wax or resin, an oil rendered from animal fat, an algal oil, an oil rendered from the pyrolysis of sewage sludge or agricultural waste, a byproduct liquid from processing of a biogenic material, a liquid produced by hydrothermal liquefaction of a biomaterial, a crude tall oil, a tall oil rosin, a tall oil pitch, or a tall oil fatty acid, an oil produced from recycled material, an oil derived from the pyrolysis of off-quality, rejected, or end-of-life tires, an oil derived from the pyrolysis of discarded or recycled plastics or rubber products, an oil derived from the pyrolysis of municipal solid waste, or an oil derived from the pyrolysis of biomass, or any combinations thereof. These liquid feedstocks have an atomic H:C ratio greater than 1.23, or a specific gravity of at most 1.02, or a BMCI value less than 100. Atomic H:C ratio may be measured according to ASTM D5291; specific gravity may be measured by ASTM D4052, BMCI may be measured according to Smith, H. M. (1940). Correlation Index To Aid In Interpreting Crude-Oil Analyses Technical Paper 610. Washington, DC, U.S. Department of the Interior, Bureau of Mines.

As noted above, second feedstock 60 is injected into the blended stream, for example, in a plane at a distance D2 from the plane in which reclaimed carbon 50 is injected into reactor 5. In general, D2 should be sufficient for reclaimed carbon 50 to blend with the reaction stream but not so long that the reaction stream is too cool to permit pyrolysis of second feedstock 60. The total jet time from the where the first feedstock 40 is injected to where the second feedstock is injected ((D1+D2)/((volumetric flow of combustion air under normal conditions)/(area of throat))) may be from 27 ms to 100 ms, for example, from 30 ms to 40 ms, from 40 ms to 50 ms, from 50 ms to 60 ms, from 60 ms to 70 ms, from 70 ms to 80 ms, or from 80 ms to 100 ms. Preferably, no quenching agent, e.g., water, is introduced to the precursor or the blended stream prior to injection of the second feedstock 60. The second feedstock 60 may be injected via a lance projecting into the interior of reactor 5, as shown in FIG. 1. The second feedstock 60 may be injected via one or more radial lances or injectors arranged on the circumference of the reactor 5 in a plane perpendicular to the flow direction, as shown in FIG. 2. The second feedstock 60 may constitute 30%-70% of the total feedstock injected into reactor 5, for example, 40%-60% or 45%-55% of the total feedstock. The second feedstock may be injected at a rate of 180 to 5000 kg/hr, for example, 190 kg/hr to 350 kg/hr, 350 kg/hr to 700 kg/hr, 700 kg/hr to 1000 kg/hr, 1000 kg/hr to 1500 kg/hr, 1500 kg/hr to 2000 kg/hr, 2000 kg/hr to 2500 kg/hr, 2500 kg/hr to 3000 kg/hr, 3000 kg/hr to 3500 kg/hr, 3500 kg/hr to 4000 kg/hr, 4000 kg/hr to 4500 kg/hr, or 4500 kg/hr to 5000 kg/hr. As shown in FIG. 1, the diameter of reaction zone 70 optionally increases before injection of the second feedstock 60. Alternatively, reaction zone 70 may be succeeded by a tapering section into a second throat 90 into which second feedstock 60 is injected (FIG. 2). In this embodiment, second feedstock 60 is preferably injected at a plurality of lances or injectors disposed about the circumference of throat 90.

The second feedstock may be preheated prior to injection into the blended stream, for example, as described in U.S. Pat. No. 9,574,087, the entire contents of which are incorporated herein by reference. Following injection, the second feedstock becomes pyrolyzed. The pyrolyzed feedstock forms deposits on at least a portion of the particles in the blended stream, both the carbon black and the reclaimed carbon. These particles are termed carbon-coated particles and may be entirely or partially (e.g., at least 99%, at least 98%, at least 95%, at least 90%, at least 85%, at least 80%, at least 75%, at least 65%, at least 60%, at least 55%, at least 50%, at least 45%, at least 40%, at least 35%, at least 30%, at least 25%, at least 20%, at least 15%, or at least 10%) coated with carbon resulting from pyrolysis of the second feedstock 60. In addition, the pyrolyzed second feedstock may form new carbon black particles. The resulting reaction stream travels to quench 80, where a quenching fluid, such as water, is directed into the reaction stream. Optionally, the quench fluid may be directed into several points of the reactor 5. The quench fluid cools the solid particles and reduces the temperature of gases in the reaction stream. Quench 80 may be 5-100 feet (1.5 m to 30.5 m) downstream of the injection of second feedstock 60, for example, 10 feet to 50 feet (3 m to 15.2 m), 30 ft to 60 feet (9.1 m to 18.3 m), 40 feet to 70 feet (12.2 m to 21.3 m), or 50 feet to 100 ft (15.2 m to 30.5 m) downstream. The final particulate carbon product may include at least 15% (by mass) material that originated as reclaimed carbon, as determined by mass balance, that is, the mass ratio of reclaimed carbon injected into the system and the carbon-coated product retrieved from the system under steady state conditions, for example, from 20% to 70%, from 25% to 40%, from 15% to 35%, from 30% to 50%, from 40% to 60%, or from 50% to 70%, with the remainder being carbon (both carbon black and coating material) formed in the reactor 5 and associated ash, sulfur, and other impurities. Ash, sulfur, and other impurities resulting from impurities in the first feedstock are typically at most 2% by weight of the particulate carbon product.

After quenching, the resulting particulate carbon blend and cooled gases pass downstream into any conventional cooling and separating apparatus. Separation of the particulate carbon blend from the reaction stream may be accomplished by any means known to those of skill in the art, including but not limited to a precipitator, a cyclone separator, or a bag filter. After the particulate carbon blend is separated from the reaction stream, it is optionally pelletized.

The particulate carbon blend may have a COAN according to ASTM D3493 of 85 to 145 mL/100 g, for example, from 95 to 140 mL/100 g, from 100 to 135 mL/100 g, from 105 to 130 mL/100 g, from 110 to 125 mL/100 g, or from 110 to 120 mL/100 g. The particulate carbon blend may have an STSA according to ASTM D6556 of 75 to 105 m²/g, for example from 80 to 100 m²/g, from 85 to 95 m²/g, from 90 to 105 m²/g, or from 95 to 105 m²/g.

The particulate carbon blend may be characterized by energy-dispersive x-ray spectroscopy (EDS) and x-ray photoelectron spectroscopy (XPS). XPS is primarily a surface analysis technique, while EDS is able to analyze the composition of the bulk sample. Thus, comparing the analysis of silicon and zinc from both of these techniques can distinguish carbon black, which has almost no Si or Zn, from reclaimed carbon, which has significant Si and Zn, both of which are used to produce tires from which rC is produced. Moreover, this comparison can also be used to identify particulate carbon produced according to the embodiments provided herein, since material deposited on the surface of the rC by feedstock pyrolysis will also have almost no Si or Zn, while these elements will still be present in the bulk of the rC particle.

In certain embodiments, a mass ratio Si/C as measured by XPS of the particulate carbon product may be at most 1%, for example, from 0.2% to 0.5% or from 0.2% to 0.35%. Alternatively or in addition, a mass ratio Si/C as measured by EDS of the particulate carbon product (Si/C (EDS)) and the mass ratio Si/C as measured by XPS (Si/C (XPS)) may satisfy Si/C (XPS)÷Si/C (EDS) is at most 1, for example at most 0.9, at most 0.8, at most 0.7, at most 0.6, at most 0.5, or from 0.1 to 1, from 0.2 to 0.9, or from 0.3 to 0.8.

The particulate carbon product according to the various embodiments herein may be combined with elastomer and optional additional particulate fillers to form elastomer composites. The resulting elastomer composite may include 30-90 phr particulate filler, for example, 30-70, 35-60, or 40-55 phr particulate filler. The particulate filler may include 2-100% particulate carbon blend, for example 5-98 wt % or 8-90 wt %, preferably 10-100 wt %, 15-90 wt %, 20-80 wt %, 25-60 wt %, 30-50 wt %, or 15 to 40% particulate carbon blend. Both natural rubber of any grade and synthetic elastomer may be used. Blends of elastomers may also be employed. For example, the particulate carbon blend may be combined with an elastomer to form a masterbatch, which is then combined with additional elastomer of the same or different composition. Alternatively or in addition, two or more elastomers may be blended prior to mixing with the particulate carbon blend. Alternatively or in addition, the elastomer composite may also contain one or more fillers aside from the particulate carbon blend, including any other fillers known to those of skill in the art for use in elastomer composites. Exemplary additional fillers include but are not limited to, silicon treated carbon black, silica coated carbon black, precipitated silica, hydrothermal carbon (i.e., carbonaceous material produced by hydrothermal carbonization of lignin or other biomass, for example, as described in U.S. Pat. No. 10,428,218 or U.S. Pat. No. 10,035,957, the contents of both of which are incorporated herein by reference), engineered polysaccharides such as those described in US2020/181370 and US2020/190270, the contents of both of which are incorporated herein by reference, and graphene, graphene oxide, reduced graphene oxide, nanocellulose, lignin, clays, nanoclays, metal oxides, metal carbonates, single walled carbon nanotubes, multi walled carbon nanotubes, and carbon nanostructures such as those described in US2014/0093728, the entire contents of which are incorporated herein by reference.

Exemplary classes of elastomers include but are not limited to rubbers, polymers (e.g., homopolymers, copolymers and/or terpolymers) of 1,3-butadiene, styrene, isoprene, isobutylene, 2,3-dialkyl-1,3-butadiene, where alkyl may be methyl, ethyl, propyl, etc., acrylonitrile, ethylene, propylene, and the like. The elastomer may have a glass transition temperature (Tg), as measured by differential scanning calorimetry (DSC), ranging from about −120° C. to about 50° C. Examples include, but are not limited to, styrene-butadiene rubbers (SBR), polybutadiene rubbers, and natural rubbers and their functionalized derivatives such as epoxidized and chlorinated rubber, polyisoprene rubbers, ethylene-propylene copolymers (e.g., EPDM), isobutylene based rubbers (e.g., butyl rubber), polychloroprene rubbers, nitrile rubbers, hydrogenated nitrile rubbers, polyisoprene rubbers, polysulfide rubbers, polyacrylate elastomers, fluoroelastomers, perfluoroelastomers, and the oil extended derivatives of any of them. Blends, co-polymers, and/or functionalized derivatives of any of the foregoing may also be used. Natural rubber may also be treated to chemically or enzymatically modify or reduce various non-rubber components.

Particular suitable synthetic rubbers include: copolymers of from about 10 to about 70 percent by weight of styrene and from about 90 to about 30 percent by weight of butadiene such as copolymer of 19 parts styrene and 81 parts butadiene, a copolymer of 30 parts styrene and 70 parts butadiene, a copolymer of 43 parts styrene and 57 parts butadiene and a copolymer of 50 parts styrene and 50 parts butadiene; polymers and copolymers of conjugated dienes such as polybutadiene, polyisoprene, polychloroprene, and the like, and copolymers of such conjugated dienes with an ethylenic group-containing monomer copolymerizable therewith such as styrene, methyl styrene, chlorostyrene, acrylonitrile, 2-vinyl-pyridine, 5-methyl-2-vinylpyridine, 5-ethyl-2-vinylpyridine, 2-methyl-5-vinylpyridine, allyl-substituted acrylates, vinyl ketone, methyl isopropenyl ketone, methyl vinyl ether, alpha-methylene carboxylic acids and the esters and amides thereof such as acrylic acid and dialkylacrylic acid amide. Also suitable for use herein are copolymers of ethylene and other high alpha olefins such as propylene, 1-butene and 1-pentene.

The elastomer composite may further comprise additives to facilitate mixing, promote vulcanization, or confer particular properties on a vulcanizate of the elastomer composite. Numerous additives are well known to those skilled in the art and include, for example, adhesion promoters, antioxidants, antiozonants, coupling agents, curatives, degradation inhibitors, plasticizers, processing aids (e.g., liquid polymers, oils and the like), oil extenders, wax, resins, flame-retardants, extender oils, lubricants, tackifiers, vulcanization activators such as zinc oxide and fatty acids, vulcanization accelerators, and a mixture of any of them. Exemplary additives include but are not limited to zinc oxide and stearic acid. The general use and selection of such additives is well known to those skilled in the art.

The particulate carbon blend and optional additional filler may be combined with elastomer as described above using any dry mixing method known to those of skill in the art.

Alternatively or in addition, the particulate carbon blend may be combined with elastomer according to the teachings of one or more of US20220332016, WO2021247153, WO2022125679, WO2022125683, WO2022125677, and WO2022125675, the entire contents of all of which are incorporated herein by reference. For example, wet pellets of particulate carbon blend and elastomer in solid form may be charged into a mixer and mixed under conditions where temperatures are controlled to remove at least a portion of the water in the pellets via evaporation. The elastomer is optionally premasticated prior to introduction of the wet pellets. The wet filler may be added all at once or in aliquots.

Any suitable mixer, such as a Banbury or Brabender mixer or other internal or closed mixer, or an open mixer, or an extruder or a continuous compounder or a kneading mixer or a combination thereof, may be employed to combine wet pellets of particulate carbon blend with elastomer. Other mixers include a kneading type internal mixer. Commercially available internal mixers from Farrel-Pomini, Harburg Freudenberger Maschinenbau GmbH (HF), Kobelco, or Pelmar Eng'r Ltd can be used. Besides the option to use inner circuits of steam or water or other fluid in the rotors, in addition or alternatively, the internal mixer can have cooling or heating jackets at one region or part or more than one region or part of the mixing chamber to control the temperature of the components being mixed therein. This can create one or more heating/cooling zones in a wall or portion of a wall of a mixer. The mixer can be a single stage mixer or a multi-stage mixer (e.g., two stages or more). Examples of mixers and designs that can be utilized are described in European Patent No. 2423253B1 and U.S. Pat. No. 7,556,419, the disclosures of which are incorporated herein by reference.

As another option, the mixer can be a continuous mixer. For example, the solid elastomer and wet filler may be mechanically worked by using one or more of a continuous internal mixer, a twin screw extruder, a single screw extruder, or a roll mill, such as those described in U.S. Pat. No. 9,855,686 B2, the disclosure of which is incorporated herein by reference. Suitable kneading and masticating devices are well known and commercially available, including for example, a Unimix Continuous Mixer and MVX (Mixing, Venting, extruding) Machine from Farrel Pomini Corporation of Ansonia, Conn., an FCM™ Farrel Continuous Mixer, a long continuous mixer from Pomini, Inc., a Pomini Continuous Mixer, twin rotor corotating intermeshing extruders, twin rotor counterrotating non-intermeshing extruders, continuous compounding extruders, the biaxial milling extruder produced by Kobe Steel, Ltd., and a Kobe Continuous Mixer. Alternative masticating apparatus suitable for use with one or more embodiments disclosed herein will be familiar to those of skill in the art.

The mixing can be performed with a mixer(s) having at least one rotor and the mixer can be one or more of the following: a kneader, a roll mill, a screw extruder, a twin-screw extruder, a multiple-screw extruder, a continuous compounder, and/or a twin-screw extruder. The mixing can be performed with a mixer(s) having at least one rotor and the mixer can have two-wing rotors, four-wing rotors, six-wing rotors, eight-wing rotors, and/or one or more screw rotors.

The mixing process to combine wet pellets of particulate carbon blend with elastomer may be a one stage (single stage) or multi-stage (multi-step) process. In a multi-stage process, one or more mixers or mixer types may be employed. For stages where an internal mixer is used, the fill factor at each such stage may independently be no more than 72%, no more than 70%, or no more than 68%, or no more than 66%, such as from about 30% to 72%, from 40% to 70%, from 45% to 70%, from 30% to 60%, from 50 to 72%, from 50 to 70%, from 50 to 68%, from 60 to 72%, from 60 to 70%, from 60 to 68%, from 65 to 72%, from 65 to 70%, from 65 to 68%, or from 40 to 60% or from 50 to 60% and the like. The temperature of the mixer may be controlled to control the temperature of the mixture, the amount of water evaporated, or both. For example, in a multi-stage process, the temperature of the mixer for each stage may be controlled to control the amount of water evaporated from the mixture in the first mixing stage and in one or more subsequent stages. For instance, the liquid content of the composite discharged can be lower than the liquid content of the material charged into the mixer by an amount of from 10% to 99.9% (wt. % vs wt. %), from 10% to 95%, or from 10% to 50%. Alternatively or in addition, the rate of rate of liquid release from the composite or mixture during mixing, e.g., by evaporation, can be measured as a time average release rate of the liquid per kg of composite or mixture (e.g., total liquid removed/(release time×composite weight), and this rate can be from 0.01 to 0.14 kg/(min·kg) or from 0.01 to 0.07 kg/(min·kg) or other rates below or above this range.

Alternatively or in addition, the mixing may be controlled in one or more stages to allow a predetermined total specific energy (energy applied to a mixing system that drives one or more rotors per mass of composite on a dry weight basis), e.g. from 1000 kJ/kg composite (or per kg mixture present in the mixer) to 10,000 kJ/kg composite (or per kg mixture present in the mixer), for example from 2,000 kJ/kg to 5,000 kJ or 1,500 kJ/kg to 8,000 kJ/kg, 1,500 kJ/kg to 7,000 kJ/kg, 1,500 kJ/kg to 6,000 kJ/kg, 1,500 kJ/kg to 5,000 kJ/kg, 1,500 kJ/kg to 3,000 kJ/kg, 1,600 kJ/kg to 8,000 kJ/kg, 1,600 kJ/kg to 7,000 kJ/kg, 1,600 kJ/kg to 6,000 kJ/kg, 1,600 kJ/kg to 5,000 kJ/kg, 1,600 kJ/kg to 4,000 kJ/kg, 1,600 kJ/kg to 3,000 kJ/kg, or other values in any of these ranges. Alternatively or in addition, the specific energy applied to the mixture may be divided to ensure a certain amount of specific energy is applied before or after a portion, e.g., 75% of the filler, is added to the mixer. That is, the filler need not be added all at once. Mixing times at each stage may be any suitable time, for example, from 1 min to 40 min, from 1 min to 20 min, from 1 min to 15 min, from 5 min to 30 min, from 5 min to 20 min, from 5 min to 15 min, or from 1 min to 12 min, from 1 min to 10 min, from 3 min to 30 min, or other times. Alternatively or in addition, the dump discharge temperature for each stage may be from 120° C. to 180° C., 120° C. to 190° C., 130° C. to 180° C., such as from 140° C. to 180° C., from 150° C. to 180° C., from 130° C. to 170° C., from 140° C. to 170° C., from 150° C. to 170° C., or other temperatures within or outside of these ranges.

Following any one or more mixing steps or stages, the resulting composite may be subjected to one or more post-processing steps, for example, to shape or form the composite and/or allow for improved handling. Post-processing may provide a composite that can be dried, homogenized, extruded, calendared, milled, granulated, cut, baled, or sheeted. The composite may be compounded and vulcanized immediately or may be held for a period of time prior to compounding. Suitable equipment for various post-processing steps include but are not limited to one or more of an internal mixer, a kneader, a roll mill, an open mill, a screw extruder, a twin-screw extruder, a multiple-screw extruder, a continuous compounder, and/or a twin screw discharge extruder fitted with a roller die (e.g., twin-screw sheeter) or fitted with stationary knives. Depending on which device or devices are used, it may be desirable to process the composite through the device more than one time or through a series of like or different devices having the same or different operating settings (e.g., speed, temperature, energy input, etc.). Alternatively or in addition, the elastomer composite may be combined with added filler, added elastomer, or both, prior to or as part of the vulcanization process. The additional filler may be the same or different as the particulate filler in the elastomer composite and may include the same or a different particulate carbon blend as provided herein or any filler known to those of skill in the art, including the additional fillers listed above. The added filler and or elastomer may increase or decrease the filler loading of the vulcanizate with respect to the elastomer composite.

To vulcanize the elastomer composite material, it is combined with a curative package including a cross-linking agent, any necessary activators and accelerators, anti-oxidant, and additional optional additives such as any of those listed above. Where sulfur is used as a cross-linking agent, typical activators include zinc oxide and or stearic acid, and typical accelerators include sulfenamides such as N-tert-butyl-2-benzothiazole sulfenamide (TBBS) and N-cyclohexyl-2-benzothiazole sulfonamide (CBS). Anti-oxidants include N-(1,3-dimethylbutyl)-N′-phenyl-p-phenylenediamine (6PPD) and those listed in WO2012/037244. Other curatives used in rubber processing are peroxides, urethane crosslinkers, metallic oxides, acetoxysilane compounds, and so forth. Additional suitable components for sulfur-based and other cross-linking systems and methods of mixing and vulcanizing elastomer composites are well known to those of skill in the art. For example, typical procedures used for rubber compounding are described in Maurice Morton, Rubber Technology, 3rd Edition, Van Norstrand Reinhold Company, New York 1987, and 2nd Edition, Van Nordstrand Reinhold Company, New York 1973.

In comparison to a vulcanizate containing an equivalent amount of ASTM N330 type carbon black and compounded and vulcanized in the same manner, a vulcanizate containing particulate carbon according to the various embodiments provided herein may have a value of M300, the stress at 300% strain as measured by ASTM D412, at least 95% as great, for example, from 97% to 140% as great, from 99% to 130% as great, from 101% to 120% as great, or from 103% to 115% as great.

In comparison to a vulcanizate containing an equivalent amount of ASTM N330 type carbon black and compounded and vulcanized in the same manner, a vulcanizate containing particulate carbon according to the various embodiments provided herein may have a log (base 10) resistivity from 105 to 125% as great, for example, from 107 to 123% as great, or from 110% to 120% as great.

In comparison to a vulcanizate containing an equivalent amount, by mass, of a reclaimed carbon and compounded and vulcanized in the same manner, a vulcanizate containing particulate carbon according to the various embodiments provided herein may have a log (base 10) resistivity from 55% to 85% as great, for example, from 55% to 75% as great. Alternatively or in addition, such a vulcanizate may have a tensile stress at 300% strain that is at least 35% greater, for example, from 35% to 70% greater, from 40% to 65% greater, or from 45% to 65% greater than the tensile stress at 300% strain of an elastomer composite prepared in the same manner and with the same formulation but with a reclaimed carbon, for example, a reclaimed carbon having 10-25 wt % ash, substituted for the particulate carbon product.

In some embodiments, vulcanized elastomer composite comprising at least one elastomer and 40-60 phr of a particulate carbon product produced from a reclaimed carbon according to the various embodiments herein may have a log (base 10) resistivity from 55% to 85% as great, for example, from 55% to 75% as great as a vulcanized elastomer composite prepared in the same manner and with the same formulation but with the uncoated reclaimed carbon substituted for the particulate carbon product. Alternatively or in addition, the vulcanized elastomer composite may have a tensile stress at 300% strain that is at least 35% greater, for example, from 35% to 70% greater, from 40% to 65% greater, or from 45% to 65% greater than the tensile stress at 300% strain of a vulcanized elastomer composite prepared in the same manner and with the same formulation but with the uncoated reclaimed carbon substituted for the particulate carbon product.

A variety of rubber articles may incorporate the vulcanizate. For example, the vulcanizate may be incorporated in a tire, e.g., pneumatic tires, non-pneumatic tires, or solid tires. For example, the vulcanizate may be incorporated in tire treads, tire carcasses, undertread, innerliners, sidewalls, sidewall inserts, wire-skim, or cushion gum for retread tires. Alternatively or in addition, the vulcanizate may be incorporated in hoses, linings, liners, seals, gaskets, anti-vibration articles, tracks, track pads for track-propelled vehicle equipment, engine mounts, earthquake stabilizers, mining equipment screens, mining equipment linings, conveyor belts, chute liners, slurry pump liners, mud pump impellers, valve seats, valve bodies, piston hubs, piston rods, plungers, impellers for mixing slurries and slurry pump impellers, grinding mill liners, cyclones and hydrocyclones, expansion joints, linings for dredge pumps and outboard motor pumps for marine equipment, shaft seals for marine, oil, aerospace, and other applications, propeller shafts, or linings for pipes to convey, e.g., oil sands or tar sands. Alternatively or in addition, the vulcanizate may be incorporated into engine mounts, bushings, weather stripping, windshield wipers, automotive components, seals, gaskets, housings, and wheel or track elements.

Various embodiments will be further clarified by the following examples which are intended to be only exemplary in nature.

### EXAMPLES

### Section 1

In all cases, decant oil was used as the first carbon black feedstock. For Examples 1-8 and 10-12, decant oil was also used as the second feedstock. In Example 9, the second feedstock was tire pyrolysis oil (Polimix 330 Heavy TPO, Polimix Ambiental, Santan do Parnaíba, Brazil) In each example, the process air rate was 1500 Nm³/h, the process air inlet temperature was 500 deg C., the equivalence ratio of burner fuel and oxidant was 0.625 (fuel lean), and the quench length was 40 ft (12.2 m). Reclaimed carbon in Examples 1-3, 5-8, and 10-12 was used as obtained from CBp Cyprus Ltd. (Limassol, Cyprus). Reclaimed carbon in Examples 4 and 9 from Delta Energy Group, LLC (Natchez, Mississippi) was jet-milled to D99<15 microns. Milled reclaimed carbon was pumped into the reactor from a loss in weight feeder. In all cases, the throat diameter Dt was 11.4 cm. Table 1 shows the flow parameters that were varied for each condition.

Utilizing a carbon black furnace process, the burner fuel (natural gas) and hot process air were combined in a combustion chamber to provide a stream of hot gases in the form of a hot combusted gas stream. The natural gas and liquid fuels were introduced and burned through combustion devices typical of the state-of-the-art. Specifically, the first carbon black forming feedstock was introduced in a throat such as that shown in the Figures. The throat was attached to a refractory-lined reactor chamber. In Examples 1-11, the reclaimed carbon (“rC”) was introduced at a rate of 50 kg/hr regardless of location; the reclaimed carbon was introduced at a rate of 100 kg/hr in Example 12. In Examples 5-12, the reclaimed carbon was introduced via a lance similar to lance 55 in FIG. 2 at a location downstream from the throat as indicated in Table 1A. In Examples 1, 2, 3 and 4, the reclaimed carbon was introduced via an axial lance 76.2 cm upstream of the injection location of the first feedstock.

Where used, the second carbon black feedstock was introduced via a radial lance similar to that shown in FIG. 1 in connection with second feedstock 60. The “Second FS location” given in Table 1A is the distance from the first feedstock injection to the second feedstock injection. The jet time in seconds between the first and second feedstock locations and from the first feedstock injection to the reclaimed carbon injection (i.e., the jet time corresponding to D1) and from the reclaimed carbon injection to the second feedstock injection (i.e., the jet time corresponding to D2) are specified in Tables 1A and 1B. Downstream of the second feedstock introduction, a water spray was used to quench at a flow rate given in Table 1A. Downstream of the quench, a filter was used to separate the particulate carbon product from the tail gas stream. The particulate carbon product was pelletized prior to measurement of STSA (according to ASTM D6556) and COAN (according to ASTM D3493), which results are in Table 1B.

TABLE 1A

| | | | | Feedstock | |
|---|---|---|---|---|---|
| | | | | rates at first | Jet time (ms) |
| | | Second FS | Quench | and second | between first |
| Ex- | | location | flow | locations | FS location |
| ample | rC Location | (cm) | (kg/h) | (kg/h) | and rC |
| 1* | Upstream | N/A | 390 | 399/— | N/A |
| 2* | Upstream | 50.8 | 435 | 236/163 | N/A |
| 3* | Upstream | 101.6 | 435 | 236/163 | N/A |
| 4* | Upstream | 127 | 500 | 272/189 | N/A |
| 5 | 50.8 cm | 101.6 | 435 | 236/163 | 12.5 |
| | downstream | | | | |
| 6 | 50.8 cm | 127 | 435 | 236/218 | 12.5 |
| | downstream | | | | |
| 7* | 50.8 cm | N/A | 470 | 399/— | 12.5 |
| | downstream | | | | |
| 8 | 76.2 cm | 127 | 435 | 236/218 | 18.8 |
| | downstream | | | | |
| 9 | 50.8 cm | 127 | 480 | 229/206 | 12.5 |
| | downstream | | | | |
| 10 | 50.8 cm | 127 | 500 | 240/221 | 12.5 |
| | downstream | | | | |
| 11 | 50.8 cm | 127 | 510 | 263/243 | 12.5 |
| | downstream | | | | |
| 12 | 50.8 cm | 127 | 475 | 240/221 | 12.5 |
| | downstream | | | | |

*Comparative Example

TABLE 1B

| | Jet time (ms) | Jet time (ms) | | | M300 |
|---|---|---|---|---|---|
| | between rC | between first | | | indexed to |
| Ex- | and second | and second | STSA | COAN | Vulcan |
| ample | FS location | FS locations | (m²/g) | (cc/100 g) | 3 CB |
| 1* | N/A | N/A | 99.8 | 73.6 | 70% |
| 2* | N/A | 12.5 | 105.8 | 78.5 | 76% |
| 3* | N/A | 25.0 | 105.8 | 88.9 | 88% |
| 4* | N/A | 31.3 | 104 | 86 | 87% |
| 5 | 12.5 | 25 | 105.5 | 89.8 | 87% |
| 6 | 18.8 | 31.3 | 88.6 | 96.4 | 108% |
| 7* | N/A | N/A | 104.5 | 83.9 | 75% |
| 8 | 12.5 | 31.3 | 87.5 | 98.8 | 108% |
| 9 | 18.8 | 31.3 | 97 | 107 | 124% |
| 10 | 18.8 | 31.3 | 95 | 95 | 98% |
| 11 | 18.8 | 31.3 | 88 | 99 | 112% |
| 12 | 18.8 | 31.3 | 79 | 93 | 113% |

The pelletized carbon product of Examples 1-8, 10, and 11 were compounded with rubber using the formulation and methods in Tables 2 and 3 below. The rubber was Kralex SBR 1502; stearic acid was rubber grade (Akrochem Corp.); zinc oxide was RGT-M (Akrochem Corp.); sulfur was Rubbermakers Sulfur (Akrochem Corp); BBTS was Accelerator BBTS (Akrochem Corp.). All compositions were mixed in a 1.6 L Banbury mixer with two wing rotors in two stages as described in Table 3. After each compounding stage, the compounds were sheeted on a 2-roll mill operated at 50° C. and about 23 rpm, followed by 3 pass-throughs and 4 end-rolls with a nip gap about 5 mm, with a rest time before next stage of mixing (or curing, after the last stage) of at least 2 hours. Curing was performed in a heated press (160° C., 130 tons), for 20 min for all samples<5 mm thick, 28 min for all samples>5 mm thick.

Tensile modulus was measured at 300% strain according to ASTM D412 and indexed to that for a vulcanizate produced in the same manner but using Vulcan 3 carbon black meeting the requirements for ASTM N330 carbon black (Cabot Corporation) (Table 1B).

TABLE 2

| Component | Amount (phr) |
|---|---|
| SBR Rubber | 100 |
| Particulate Carbon | 50 |
| Stearic Acid | 1 |
| Zinc Oxide | 3 |
| Sulfur | 1.75 |
| BBTS | 1 |

TABLE 3
Stage 1

| Fill Factor, % | 70 |
|---|---|
| Rotor Speed, rpm | 80 |
| Start Temperature, ° C. | 50 |
| Time (s) | Description |
| 0 | Add Polymer |
| 30 | Add Filler |
| 60 | Scrape/Sweep |
| 120 | add pre-blended chemicals |
| 180 | Scrape/Sweep |
| 240 | Dump |

Stage 2

| Fill Factor, % | 65 |
|---|---|
| Rotor Speed, rpm | 60 |
| Start Temperature, ° C. | 50 |
| Time (s) | Description |
| 0 | Add previous stage batch and curatives |
| 30 | Scrape/Sweep |
| 90 | Dump - Adjust RPM to stay <110° C. |

The pelletized carbon products of Examples 9 and 12 were compounded with rubber using the formulation and methods in Tables 4 and 5 and below. The rubber was Kralex SBR 1502; stearic acid was rubber grade (Akrochem Corp.); zinc oxide was RGT-M (Akrochem Corp.); sulfur was Rubbermakers Sulfur (Akrochem Corp); BBTS was Accelerator BBTS (Akrochem Corp.). All compositions were mixed in a 1.77 L HF INTERMIX E series intermesh mixer in two stages as described in Table 5. After each compounding stage, the compounds were sheeted on a 2-roll mill operated at 50° C. and about 23 rpm, followed by 3 pass-throughs and 4 end-rolls with a nip gap about 5 mm, with a rest time before next stage of mixing (or curing, after the last stage) of at least 2 hours. Curing was performed in a heated press (160° C., 130 ton), for 26 min for all samples<5 mm thick, 34 min for all samples>5 mm thick.

Tensile modulus was measured at 300% strain according to ASTM D412 and indexed to that for a vulcanizate produced in the same manner but using Vulcan 3 carbon black (Cabot Corporation) (Table 1B).

TABLE 4

| Component | Amount (phr) |
|---|---|
| SBR Rubber | 100 |
| Particulate Carbon | 50 |
| Stearic Acid | 1 |
| Zinc Oxide | 3 |
| Sulfur | 1.75 |
| BBTS | 1 |

TABLE 5
Stage 1

| Fill Factor, % | 70 |
|---|---|
| Rotor Speed, rpm | 80 |
| Start Temperature, ° C. | 50 |
| Time (s) | Description |
| 0 | Add Polymer |
| 60 | Add Filler |
| 90 | Scrape/Sweep |
| 150 | add pre-blended chemicals |
| 210 | Scrape/Sweep |
| 270 | Dump |

Stage 2

| Fill Factor, % | 65 |
|---|---|
| Rotor Speed, rpm | 60 |
| Start Temperature, ° C. | 50 |
| Time (s) | Description |
| 0 | Add previous stage batch and curatives |
| 30 | Scrape/Sweep |
| 90 | Dump - Adjust RPM to stay <110° C. |

### Section 2

Particulate carbon was produced as in Section 1, except as noted in Tables 6 and 7 below. The reclaimed carbon was introduced at a location 50.8 cm downstream from the throat at a rate as indicated in Table 6. Examples 13 and 14 employed reclaimed carbon from CBp Cyprus Ltd. (Limassol, Cyprus) jet-milled to D99<15 microns. Reclaimed carbon in Examples 15 and 16 was obtained from Delta Energy Group, LLC and jet-milled to D99<15 microns. Rubber was compounded as described for Examples 1-8, 10 and 11 (Example 15) or as described for Examples 9 and 12 (Examples 13 and 14) to measure mechanical properties.

TABLE 6

| | | | | Feedstock | |
|---|---|---|---|---|---|
| | | | | rates at first | Jet time (ms) |
| | | Second FS | Quench | and second | between first |
| | rC rate | location | flow | locations | FS location |
| Example | (kg/h) | (cm) | (kg/h) | (kg/h) | and rC |
| 13 | 100 | 127 | 475 | 240/221 | 12.5 |
| 14 | 100 | 127 | 435 | 240/221 | 12.5 |
| 15 | 86 | 127 | 475 | 240/221 | 12.5 |
| 16 | 86 | 127 | 475 | 263/243 | 12.5 |

TABLE 7

| | Jet time (ms) | Jet time (ms) | | | M300 |
|---|---|---|---|---|---|
| | between rC | between first | | | indexed to |
| Ex- | and second | and second | STSA | COAN | Vulcan |
| ample | FS location | FS locations | (m²/g) | (cc/100 g) | 3 CB |
| 13 | 18.8 | 31.3 | 79 | 93 | 112% |
| 14 | 18.8 | 31.3 | 79 | 93 | 113% |
| 15 | 18.8 | 31.3 | 84 | 91 | 102% |
| 16 | 18.8 | 31.3 | 78 | 94 | 103% |

### Section 3

Particulate carbon from Examples 12-15, Vulcan 3 carbon black (Cabot Corporation), reclaimed carbon (Delta Energy; jet-milled to D99<15 microns), and blends of 30% reclaimed carbon (Delta Energy; jet-milled to D99<15 microns) and 70% N330 type carbon black (Vulcan 3 carbon black, Cabot Corporation) were formed into vulcanizates using the formulations and mixing protocols described in Tables 8-11 below. Napthenic oil was Calight RPO (R.E. Carroll, Inc.). Antioxidant (2,2,4-trimethyl-1,2-dihydroquinoline (TMQ)) was Antioxidant DQ from Akrochem. Akrowax 5031 beads were obtained from Akrochem. The natural rubber was STR 20 grade. The butadiene rubber was Buna CB24 from Arlanxeo. All other components were as described above. All compositions were mixed in a 1.77 L HF INTERMIX E series intermesh mixer in two stages as described in Table 5. After each compounding stage, the compounds were sheeted on a 2-roll mill operated at 50° C. and about 23 rpm, followed by 3 pass-throughs and 4 end-rolls with a nip gap about 5 mm, with a rest time before next stage of mixing (or curing, after the last stage) of at least 2 hours. Curing was performed in a heated press (160° C., 130 ton), for 26 min for all samples<5 mm thick, 34 min for all samples>5 mm thick. The rC-carbon black blend was produced by combining pellets of reclaimed carbon and pellets of virgin carbon black with rubber (as opposed to pellets containing both reclaimed carbon and virgin carbon black). The formulations in Tables 8-10 are meant to approximate typical formulations for TBR (truck, bus, radial) sidewalls (SW), passenger car (PC) carcass ply, and undertread (UT), respectively.

TABLE 8
TBR sidewall formulation

| | Experimental | Comparative |
|---|---|---|
| | rubber | Example |
| Component | Amount (phr) | Amount (phr) |
| Natural Rubber | 50 | 50 |
| Polybutadiene | 50 | 50 |
| Particulate Carbon | 50 | — |
| N330 type carbon black | — | 50 |
| Naphthenic Oil | 10 | 10 |
| 6PPD | 3 | 3 |
| Antioxidant | 1 | 1 |
| Wax | 1 | 1 |
| Stearic Acid | 2 | 2 |
| Zinc Oxide | 3 | 3 |
| Sulfur | 2 | 2 |
| BBTS | 1 | 1 |

TABLE 9
PC Carcass Ply

| | Experimental | Comparative |
|---|---|---|
| | rubber | Example |
| Component | Amount (phr) | Amount (phr) |
| Natural Rubber | 70 | 70 |
| SBR Rubber | 30 | 30 |
| Particulate Carbon | 45 | — |
| N330 type carbon black | — | 45 |
| Naphthenic oil | 8 | 8 |
| 6PPD | 1 | 1 |
| Antioxidant | 1 | 1 |
| Stearic Acid | 2 | 2 |
| Zinc Oxide | 5 | 5 |
| Sulfur | 2.5 | 2.5 |
| BBTS | 0.9-1 | 0.9-1 |

TABLE 10
Undertread

| Component | Amount (phr) | Amount (phr) |
|---|---|---|
| Natural Rubber | 100 | 100 |
| Particulate Carbon | 50 | — |
| N330 type carbon black | — | 50 |
| Naphthenic oil | 5 | 5 |
| 6PPD | 3 | 3 |
| Antioxidant | 1 | 1 |
| Stearic Acid | 2 | 2 |
| Zinc Oxide | 3 | 3 |
| Sulfur | 2 | 2 |
| BBTS | 0.85-1 | 0.85-1 |

TABLE 11
Stage 1

| Fill Factor, % | 73 |
|---|---|
| Rotor Speed, rpm | 70 |
| Start Temperature, ° C. | 73 |
| Time (s) | Description |
| 0 | Add Polymer |
| 60 | Add ⅔ Filler |
| 60 | Scrape/Sweep |
| 120 | Add remaining filler + oil |
| 120 | Scrape/Sweep |
| 180 | Add remaining chemicals |
| 180 | Scrape/Sweep |
| 240 | Scrape/Sweep |
| 300 | Dump - adjust RPM to stay <155° C. |

Stage 2

| Fill Factor, % | 68 |
|---|---|
| Rotor Speed, rpm | 60 |
| Start Temperature, ° C. | 57 |
| Time (s) | Description |
| 0 | Add previous stage batch and curatives |
| 30 | Scrape/Sweep |
| 90 | Dump - Adjust RPM to stay <110° C. |

Resistivity of these materials was measured as follows. Rubber sheets were prepared as for ASTM D412, Test Method A. A 2 in.×5 in. specimen was cut from the sheet with a die, being careful to keep the sample flat. A template was used to apply conductive silver paint (Conductive Silver 187 (Ted Pella) diluted with acetone as necessary to achieve paint-like consistency) in even strips on both ends, including both sides and the edges. The prepared sample was placed on a flat, non-conductive base, and current supply electrodes were attached by metal bars at a fixed distance from one another at the ends of the sheet using a spring-loaded device that applied constant load. Resistance was measured with a voltmeter. Measurements were made in duplicate and converted to resistivity by multiplying by the measured width and thickness of the sample and dividing by the distance between the electrodes. The average is reported in Table 12 below; duplicate batches were prepared for N330 CB and Example 13, with the results averaged across the two batches. The results show that production of particulate carbon according to the embodiments herein provides resistivity improvement even beyond simple blending of equivalent amounts of virgin carbon black and rC. The percentage of rC by mass in experimental materials was calculated using mass balance techniques. M300, the tensile stress at 300% strain, was measured according to ASTM D412.

TABLE 12

| | Log 10 | | | |
|---|---|---|---|---|
| | Resistivity | Tire | | M300 |
| Particulate filler | (ohm · cm) | Component | rC % | (MPa) |
| N330 CB | 2.9 | SW | 0 | 11.2 |
| N330 CB | 2.8 | CP | 0 | 14.2 |
| N330 CB | 2.6 | UT | 0 | 14.4 |
| rC - CB blend | 4.5 | SW | 30 | 9.67 |
| rC - CB blend | 4.6 | CP | 30 | 13.8 |
| rC - CB blend | 4.1 | UT | 30 | 13.2 |
| 100% rC | 9.3 | SW | 100 | 7.43 |
| 100% rC | 8.6 | CP | 100 | 9.7 |
| 100% rC | 9.2 | UT | 100 | 9.75 |
| Example 12 | 2.6 | SW | 34 | 12.4 |
| Example 12 | 2.6 | CP | 34 | 16 |
| Example 12 | 2.2 | UT | 34 | 15.6 |
| Example 13 | 3.4 | SW | 31 | 12.0 |
| Example 13 | 3.5 | CP | 31 | 15.0 |
| Example 13 | 2.7 | UT | 31 | 16.1 |
| Example 14 | 3.5 | SW | 30 | 10.8 |
| Example 14 | 3.6 | CP | 30 | 13.9 |
| Example 14 | 3.1 | UT | 30 | 13.5 |
| Example 15 | 3.1 | SW | 27 | 11.4 |
| Example 15 | 3.2 | CP | 27 | 15.2 |
| Example 15 | 2.6 | UT | 27 | 15.4 |

### Section 4

Samples (N330 type carbon black (IRB 9), reclaimed carbon powder (Cyprus and Delta Energy, jet-milled to D99<15 microns), particulate carbon (Examples 1, 13, and 16), a blend of 69% N330 carbon black and 31% Cyprus reclaimed carbon (rC jet-milled to D99<15 microns), and a blend of 75% N330 carbon black and 25% Delta Energy reclaimed carbon (rC jet-milled to D99<15 microns) were analyzed by energy-dispersive x-ray spectroscopy (EDS) and x-ray photoelectron spectroscopy (XPS). The blend of N330 carbon black and reclaimed carbon was produced from a blend of carbon black pellets and reclaimed carbon pellets. Samples in pellet form were prepared by gently grinding 5-10 g of pellets in a mortar and pestle. Then, 2 g of ground sample was loaded into a steel beaker with 50 g deionized water and 1 g of isopropanol. The sample was then dispersed by a Branson 450D horn sonicator with ½ Ti tip for 10 min at 20% amplitude surrounded by an ice bath. The sonicated sample dispersion was placed into a vacuum oven for drying.

For EDS, a layer of the dried sample powder was loaded onto carbon tape affixed to an aluminum stub with a powder layer thickness larger than 500 μm and an area larger than 3 mm×3 mm. The incident electron beam energy was set at 20 keV and the working distance was set up at an optimized position for the instrument configuration used, ex., 5.5 mm for the Zeiss UltraPlus SEM/Oxford XMax detector. EDS maps and sum spectra over a 135 μm×100 μm area were collected at three locations and composition data averaged.

For XPS, sample powder was loaded into a 3 mm diameter sample well for measurement. The instrument used for these measurements was a Thermo K-Alpha X-ray Photoelectron Spectrometer (XPS). The excitation source used was a monochromatic X-ray beam producing the aluminum k-alpha line. The source produced an elliptical spot size on the sample of ~0.4 mm by ~0.8 mm. For the survey scans, the instrument was set to allow the greatest sensitivity at a pass energy of 200 eV. A step size of 0.8 eV was used over the range of 0 to 1100 eV in binding energy. Between 8 and 12 sweeps were selected in order to produce high signal-to-noise spectra. Data analysis was performed using the software Thermo Avantage with the sensitivity factors provided by the manufacturer. Two different locations of each sample were measured for data averaging. Table 13 presents elemental analysis (all values in wt %) from the various samples.

TABLE 13

| | Zn | Si | Zn | Si | C | C |
|---|---|---|---|---|---|---|
| Sample | (EDS) | (EDS) | (XPS) | (XPS) | (EDS) | (XPS) |
| Example 1 | 0.36 | 0.27 | 0.35 | 0 | 97.36 | 97.6 |
| N330 CB | 0.00 | 0.02 | 0.00 | 0.53 | 97.35 | 97.43 |
| Cyprus rC | 4.01 | 1.73 | 2.96 | 5.91 | 85.14 | 78.66 |
| 69/31 blend | 1.33 | 0.61 | 1.05 | 1.80 | 93.97 | 91.26 |
| Example 13 | 0.83 | 0.64 | 0.53 | 0.23 | 95.28 | 96.22 |
| Delta rC | 3.79 | 2.86 | 3.84 | 7.60 | 82.19 | 73.12 |
| 75/25 blend | 0.80 | 0.61 | 0.60 | 1.30 | 84.65 | 93.60 |
| Example 16 | 0.27 | 0.50 | 0.54 | 0.23 | 93.87 | 96.61 |

Table 14 gives the weight ratios of silicon and zinc with respect to carbon by mass and the weight ratios of surface silica to bulk silica. The results show that more Si is present at higher concentrations in the near-surface region of reclaimed carbon than in particulate carbon produced according to the embodiments herein, suggesting that the processes provided herein add carbon to the surface of the reclaimed carbon and covering the higher silicon surface of the rC. In addition, while the bulk ratio of silicon/carbon is similar in the direct mixture of carbon black and reclaimed carbon and the particulate carbon of Example 13, the bulk ratio of zinc (measured by EDS, Table 13) is less in the particulate carbon of Example 13. This suggests that the processes provided herein also remove zinc from the reclaimed carbon.

TABLE 14

| | Shell wt. | Bulk wt. | Shell wt. | (Shell Si/C |
|---|---|---|---|---|
| | ratio of | ratio of | ratio of | ratio)/(Bulk |
| Sample | Si/C (%) | Si/C (%) | Zn/C (%) | Si/C ratio) |
| Example 1 | 0 | 0.28 | 0.37 | 0 |
| N330 CB | 0.005 | 0 | 0 | 1.00 |
| Cyprus rC | 7.51 | 2.03 | 3.76 | 3.7 |
| 69/31 blend | 1.97 | 0.65 | 1.15 | 3 |
| Example 13 | 0.24 | 0.67 | 0.56 | 0.36 |
| Delta rC | 10.39 | 3.48 | 5.25 | 3.0 |
| 75/25 blend | 1.39 | 0.72 | 0.64 | 1.9 |
| Example 16 | 0.24 | 0.53 | 0.55 | 0.45 |

The particulate carbon of Example 1 has practically no silicon in the shell despite having measurable silica in the bulk. This suggests that the carbon coating on Example 1 is quite substantial, even though the performance of rubber produced with this carbon exhibited the poorest performance. The use of the processes provided herein not only enhance the carbon concentration at the surface but also provide surface and morphology properties more favorable for rubber reinforcement.

### Section 5

Particulate carbon is made as described for Example 12, except that the feedstock rate at the second location is increased to 350 kg/hr. The resulting particulate carbon is expected to have a lower surface area than that of Example 12 and a surface silicon concentration as measured by XPS of 0.

The foregoing description of preferred implementations of the present embodiments has been presented for the purposes of illustration and description. Modifications and variations are possible in light of the above teachings, or may be acquired from practice of the embodiments. The embodiments were chosen and described in order to explain the principles of implementation and their practical application to enable one skilled in the art to utilize the embodiments in various embodiments and with various modifications as are suited to the particular use contemplated.

What is claimed is:

1. A method of making a particulate carbon product comprising:
introducing to a reactor a first carbon black forming feedstock and combining the first carbon black-forming feedstock with a stream of hot gases to form a precursor comprising a reaction stream and a particulate comprising at least 98% carbon black;
introducing reclaimed carbon particles to the precursor to form a blended stream of the carbon black and the reclaimed carbon particles in the reaction stream;
introducing a second feedstock to the blended stream wherein at least a portion of the particulate in the blended stream becomes carbon-coated particles, thereby forming a particulate carbon product comprising the carbon-coated particles; and
recovering the particulate carbon product.

2. (canceled)

3. The method of claim 1, wherein the first carbon black feedstock is a liquid at room temperature and pressure, and has the following properties:
a Bureau of Mines Correlation Index (BMCI)≥100,
an atomic H:C ratio of ≤1.23, and
a specific gravity>1.02, and
wherein the second feedstock has at least one of the following properties:
a Bureau of Mines Correlation Index (BMCI)<100, or
an atomic H:C ratio of >1.23, or
a specific gravity of ≤1.02, or
is a gas at room temperature and pressure.

4. (canceled)

5. The method of claim 1, wherein the first feedstock is 30%-70% by mass of the total carbon black yielding feedstock introduced to the reactor.

6. (canceled)

7. The method of claim 1, further comprising forming the stream of hot gases in a combustion zone having a diameter, and introducing the first carbon black-forming feedstock in a throat having a diameter Dt smaller than the diameter of the combustion zone, wherein a jet time from a first plane in which the first feedstock is introduced to the reactor and a second plane in which the second feedstock is from 27 ms to 100 ms, wherein the jet time is (distance from the first plane to the second plane)/((volumetric flow of combustion air under normal conditions)/(area of throat)).

8. (canceled)

9. (canceled)

10. (canceled)

11. The method of claim 1, wherein a jet time from a first plane in which the first feedstock is introduced to the reactor to a third plane where the reclaimed carbon is introduced to the reactor is from 7 ms to 21 ms, wherein the jet time is defined as (distance from the first plane to the third plane)/((volumetric flow of combustion air under normal conditions)/(cross-sectional area of first plane)).

12. (canceled)

13. The method of claim 1, wherein the reclaimed carbon is injected into the reactor via ports distributed about a circumference of a cross-sectional of the reactor or via a lance projecting into the interior of the reactor.

14. (canceled)

15. (canceled)

16. The method of claim 1, wherein the second feedstock is injected via a lance projecting into the interior of the reactor or via one or more radial lances or injectors arranged on the circumference of the reactor.

17. (canceled)

18. The method of claim 1, wherein a feed rate of the second feedstock is 180 to 5000 kg/hr.

19. (canceled)

20. The method of claim 1, wherein the final particulate carbon product comprises at least 15% (by mass) material that originated as reclaimed carbon.

21. The method of claim 1, wherein the particulate carbon product has a COAN according to ASTM D3493 of 85 to 145 mL/100 g.

22. A particulate carbon product comprising carbon-coated reclaimed carbon, wherein a ratio Si/C as measured by energy dispersive x-ray spectroscopy (EDS) (Si/C (EDS)) and a ratio Si/C as measured by x-ray photoelectron spectroscopy (XPS) (Si/C (XPS)) satisfy Si/C (XPS)÷Si/C (EDS) of at most 1, and a tensile stress at 300% strain of an elastomer composite comprising 40-60 phr of the particulate carbon product is at least 95% as great as the tensile stress at 300% strain of an elastomer composite prepared in the same manner and with the same formulation but with N330 carbon black substituted for the particulate carbon product.

23. A particulate carbon product comprising carbon-coated reclaimed carbon, wherein a ratio Si/C as measured by energy dispersive x-ray spectroscopy (EDS) (Si/C (EDS)) and a ratio Si/C as measured by x-ray photoelectron spectroscopy (XPS) (Si/C (XPS)) satisfy Si/C (XPS)÷Si/C (EDS) from 0.1 to 1.

24. A vulcanized elastomer composite comprising the carbon-coated reclaimed carbon of claim 23.

25. A particulate carbon product comprising carbon-coated reclaimed carbon, wherein a ratio Si/C as measured by x-ray photoelectron spectroscopy (XPS) (Si/C (XPS)) is from 0.2% to 1%.

26. (canceled)

27. A vulcanized elastomer composite comprising the particulate carbon product of claim 25.

28. A particulate carbon product comprising carbon-coated reclaimed carbon, wherein a ratio Si/C as measured by x-ray photoelectron spectroscopy (XPS) (Si/C (XPS)) is at most 1%, wherein a tensile stress at 300% strain of an elastomer composite comprising 40-60 phr of the particulate carbon product is at least 95% as great as the tensile stress at 300% strain of an elastomer composite prepared in the same manner and with the same formulation but with ASTM N330 carbon black substituted for the particulate carbon product.

29. A particulate carbon product comprising carbon-coated reclaimed carbon, wherein, in comparison to a vulcanizate containing an equivalent amount of ASTM N330 type carbon black and that is compounded and vulcanized in the same manner, a vulcanizate containing 40-60 phr of the particulate carbon product has a log (base 10) resistivity from 105 to 125% as great and a tensile stress at 300% strain at least 95% as great.

30. A particulate carbon product comprising carbon-coated reclaimed carbon, wherein a vulcanizate containing 40-60 phr of the particulate carbon product has a log (base 10) resistivity from 55% to 85% as great and a tensile stress at 300% strain that is at least 35% greater than the tensile stress at 300% strain of a vulcanizate prepared in the same manner and with the same formulation but with the uncoated reclaimed carbon substituted for the particulate carbon product.

31. A particulate carbon product comprising carbon-coated reclaimed carbon, wherein a vulcanizate containing 40-60 phr of the particulate carbon product has a log (base 10) resistivity from 55% to 85% as great and a tensile stress at 300% strain that is at least 35% greater than the tensile stress at 300% strain of a vulcanizate prepared in the same manner and with the same formulation but with a reclaimed carbon that has not been carbon-coated substituted for the particulate carbon product.

32. (canceled)

33. The particulate carbon product of claim 23, wherein particulate carbon product comprises at least 15% (by mass) reclaimed carbon.

34. The particulate carbon product of claim 23, wherein the particulate carbon product has a COAN according to ASTM D3493 of 85 to 145 mL/100 g.

35. A vulcanized elastomer composite comprising at least one elastomer and 40-60 phr of a particulate carbon product comprising carbon-coated reclaimed carbon, wherein a ratio Si/C of the particulate carbon product as measured by energy dispersive x-ray spectroscopy (EDS) (Si/C (EDS)) and a ratio Si/C as measured by x-ray photoelectron spectroscopy (XPS) (Si/C (XPS)) satisfy Si/C (XPS)+Si/C (EDS) of at most 1, and a tensile stress at 300% strain of the elastomer composite is at least 95% as great as the tensile stress at 300% strain of a vulcanized elastomer composite prepared in the same manner and with the same formulation but with N330 carbon black substituted for the particulate carbon product.

36. A vulcanized elastomer composite comprising at least one elastomer and 40-60 phr of a particulate carbon product comprising carbon-coated reclaimed carbon, wherein a ratio Si/C of the particulate carbon product as measured by x-ray photoelectron spectroscopy (XPS) (Si/C (XPS)) is at most 1%, and a tensile stress at 300% strain of the elastomer composite is at least 95% as great as the tensile stress at 300% strain of a vulcanized elastomer composite prepared in the same manner and with the same formulation but with ASTM N330 carbon black substituted for the particulate carbon product.

37. A vulcanized elastomer composite comprising at least one elastomer and 40-60 phr of a particulate carbon product comprising carbon-coated reclaimed carbon, wherein, in comparison to a vulcanizate containing an equivalent amount of ASTM N330 type carbon black and that is compounded and vulcanized in the same manner, the vulcanized elastomer composite has a log (base 10) resistivity from 105 to 125% as great and a tensile stress at 300% strain at least 95% as great.

38. A vulcanized elastomer composite comprising at least one elastomer and 40-60 phr of a particulate carbon product comprising carbon-coated reclaimed carbon, wherein the vulcanized elastomer composite has a log (base 10) resistivity from 55% to 85% as great and a tensile stress at 300% strain that is at least 35% greater than the tensile stress at 300% strain of a vulcanized elastomer composite prepared in the same manner and with the same formulation but with the uncoated reclaimed carbon substituted for the particulate carbon product.

39. A vulcanized elastomer composite comprising at least one elastomer and 40-60 phr of a particulate carbon product comprising carbon-coated reclaimed carbon, wherein the vulcanized elastomer composite has a log (base 10) resistivity from 55% to 85% as great, and a tensile stress at 300% strain that is at least 35% greater than the tensile stress at 300% strain of a vulcanized elastomer composite prepared in the same manner and with the same formulation but with a reclaimed carbon that has not been carbon coated substituted for the particulate carbon product.

40. The vulcanized elastomer composite of claim 39, wherein the reclaimed carbon that has not been carbon coated comprises 10-25 wt % ash.

41. (canceled)

42. The vulcanized elastomer composite of claim 24, wherein the particulate carbon product comprising carbon-coated reclaimed carbon comprises at least 15% (by mass) reclaimed carbon.

43. The vulcanized elastomer composite of claim 24, wherein the particulate carbon product has a COAN according to ASTM D3493 of 85 to 145 mL/100 g.

44. An article comprising the vulcanized elastomer composite of claim 24, the article being selected from tire treads, undertread, innerliners, sidewalls, sidewall inserts, wire-skim, and cushion gum for retread tires.

45. An article comprising the vulcanized elastomer composite of claim 24, the article being selected from hoses, linings, liners, seals, gaskets, anti-vibration articles, tracks, track pads for track-propelled vehicle equipment, engine mounts, earthquake stabilizers, mining equipment screens, mining equipment linings, conveyor belts, chute liners, slurry pump liners, mud pump impellers, valve seats, valve bodies, piston hubs, piston rods, plungers, impellers for mixing slurries and slurry pump impellers, grinding mill liners, cyclones and hydrocyclones, expansion joints, linings for dredge pumps and outboard motor pumps for marine equipment, shaft seals for marine, oil, aerospace, and other applications, propeller shafts, pipe linings, engine mounts, bushings, weather stripping, windshield wipers, automotive components, seals, gaskets, housings, wheel elements, and track elements.
